(19) United States
(12) Patent Application Publication
(10) Pub. No.: US 2006/0252236 A1
(43) Pub. Date: Nov. 9, 2006

(54) Method for manufacturing a semiconductor device

(76) Inventors: Cheng-Chuan Chen, Tainan Hsien (TW); Ming-Chang Chen, Tainan Hsien (TW); Kun-Ming Hung, Tainan Hsien (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/417,008

(22) Filed: May 2, 2006

(30) Foreign Application Priority Data
May 4, 2005 (TW) 094114375

(51) Int. Cl. H01L 21/20; H01L 21/36

(52) U.S. Cl. 438/481

(57) ABSTRACT

A method for manufacturing a semiconductor device includes forming an island-patterned layer of a first semiconductor material, which includes a plurality of separated islands, on a semiconductor substrate, and epitaxially growing a base layer of a second semiconductor material on the island-patterned layer.

### CROSS-REFERENCE TO RELATED APPLICATION

This application claims priority of Taiwanese application no. 94114375, filed on May 4, 2005.

### BACKGROUND OF THE INVENTION

1. Field of the Invention

This invention relates to a method for manufacturing a semiconductor device, more particularly to a method for manufacturing a semiconductor device involving formation of an island-patterned layer on a semiconductor substrate.

2. Description of the Related Art

In general, light emitting devices made from a gallium nitride-based material have unsatisfactory light extraction efficiency. The unsatisfactory light extraction efficiency primarily results from lattice mismatch between a substrate, such as a silicon carbide substrate or a sapphire substrate, and a gallium nitride-based layer formed thereon. That is, the boundary between the substrate and the gallium nitride-based layer forms a heterojunction with lattice and thermal discontinuity, and numerous dislocations take place across the gallium nitride-based layer. These dislocations will extend into an active layer formed on the gallium nitride-based layer, which results in an adverse effect on performance of the light emitting device.

In order to improve the performance of the light emitting devices, a light emitting device fabricated by forming a GaN buffer layer on the silicon carbide substrate or the sapphire substrate at a lower temperature, followed by epitaxy growth of the gallium nitride-based layer on the GaN buffer layer at a higher temperature, has been proposed (see Japanese unexamined patent publication no. 06-196757). Although the defect density of the light emitting device made by the above method can be reduced to 10¹¹ to 10¹² μm⁻², the defect density as such is still insufficient to result in a satisfactory light efficiency.

In addition, lateral epitaxy overgrowth (LEO) has been proposed to reduce the defect density of the light emitting device to as low as 10⁶ μm⁻². However, since the lateral epitaxy overgrowth process is complicated and requires a long time for performing the epitaxy growth, the production cost of the light emitting device made by LEO is relatively high.

Hence, there is a need in the art to provide an economical method for manufacturing a semiconductor device with improved light extraction efficiency.

### SUMMARY OF THE INVENTION

Therefore, the object of the present invention is to provide a method for manufacturing a semiconductor device. The method includes forming an island-patterned layer of a first semiconductor material, which includes a plurality of separated islands, on a semiconductor substrate, and epitaxially growing abase layer of a second semiconductor material on the island-patterned layer.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a fragmentary schematic view to illustrate the step of forming a seed layer on a semiconductor substrate in the first example of a method for manufacturing a semiconductor device according to this invention;

FIG. 2 is a fragmentary schematic view to illustrate the step of forming an island-patterned layer on the seed layer in the first example of this invention;

FIG. 3 is a fragmentary schematic view to illustrate the step of forming a barrier layer on the island-patterned layer in the first example of this invention;

FIG. 4 is a fragmentary schematic view to illustrate the step of forming a base layer on the barrier layer in the first example of this invention;

FIG. 5 is a fragmentary schematic view to illustrate the step of forming a continuous layer on a semiconductor substrate in the second example of a method for manufacturing a semiconductor device according to this invention;

FIG. 6 is a fragmentary schematic view to illustrate the step of forming the continuous layer into an island-patterned layer in the second example of this invention;

FIG. 7 is a fragmentary schematic view to illustrate the step of forming a barrier layer on the island-patterned layer in the second example of this invention; and

FIG. 8 is a fragmentary schematic view to illustrate the step of forming a base layer on the barrier layer in the second example of this invention.

### DETAILED DESCRIPTION OF THE PREFERRED EMBODIMENTS

The preferred embodiment of a method for manufacturing a semiconductor device according to this invention includes forming an island-patterned layer of a first semiconductor material, which includes a plurality of separated islands, on a semiconductor substrate, and epitaxially growing a base layer of a second semiconductor material on the island-patterned layer.

The semiconductor substrate suitable for use in the method of this invention may vary and is known to one skilled in the art. Preferably, the semiconductor substrate is made from a material selected from the group consisting of silicon carbide (SiC), sapphire (Al₂O₃), lithium aluminate (γ-LiAlO₂), zinc oxide (ZnO), aluminum nitride (AlN), and silicon (Si).

In detail, crystallographic orientations of both the island-patterned layer and the base layer depend upon the crystallographic orientation of the semiconductor substrate. That is to say, when the island-patterned layer and the base layer are formed on C plane of a SiC substrate or on C plane of a sapphire substrate, the island-patterned layer and the base layer thus made will have a C-plane crystallographic orientation.

The first semiconductor material used in forming the island-patterned layer may be selected from the group consisting of gallium nitride-based compounds. Preferably, the first semiconductor material is the gallium nitride-based compound having a formula of AlₓIn_{y}Ga_{1-x-y}N, in which 1>x≧0, 1>y≧0, and 1≧1−x−y>0.

The island-patterned layer may be formed on the semiconductor substrate through metalorganic chemical vapor deposition (MOCVD) techniques. A non-limiting example of the first semiconductor material is the gallium nitride-based compound having a formula of AlₓIn_{y}Ga_{1-x-y}N, in which x=0 and y=0, i.e., GaN. Formation of the island-patterned layer of GaN is conducted by reacting a gallium source gas with an ammonia gas at a reaction temperature ranging from 500° C. to 1100° C. Preferably, reaction of the gallium source gas with the ammonia gas is conducted at a reaction temperature ranging from 700° C. to 1100° C. Non-limiting examples of the gallium source gas include trimethylgallium (TMGa) and triethylgallium (TEGa).

Another non-limiting example of the first semiconductor material is the gallium nitride-based compound having a formula of AlₓIn_{y}Ga_{1-x-y}N, in which 1>x≧0, 1>y≧0, and 1>1−x−y>0. Formation of the island-patterned layer is conducted by reacting the gallium source gas with the ammonia gas, an aluminum source gas and an indium source gas at a reaction temperature ranging from 500° C. to 1100° C. Preferably, reaction of the gallium source gas with the ammonia gas, the aluminum source gas and the indium source gas is conducted at a reaction temperature ranging from 700° C. to 1100° C. A non-limiting example of the aluminum source gas is trimethylaluminum (TMA), and a non-limiting example of the indium source gas is trimethylindium (TMIn).

In addition, non-limiting examples of a carrier gas suitable for use in formation of the island-patterned layer include hydrogen gas (H₂) and nitrogen gas (N₂).

Preferably, the island-patterned layer is formed through MOCVD in combination with silicon-doping so as to increase the height-to-width ratio of each of the separated islands in the island-patterned layer. Increase of the height-to-width ratio of each of the separated islands enhances lateral epitaxy growth of the base layer of the second semiconductor material.

Alternatively, the island-patterned layer including the separated islands may be formed on the semiconductor substrate by: forming a continuous layer of the first semiconductor material on the semiconductor substrate through reacting a gallium source gas with an ammonia gas at a reaction temperature ranging from 500° C. to 700° C.; and subsequently raising the reaction temperature to 900° C. to 1100° C. and lowering the partial pressure of the ammonia gas so as to form the continuous layer of the first semiconductor material into the island-patterned layer. Preferably, formation of the continuous layer and formation of the continuous layer into the island-patterned layer are both conducted through MOCVD techniques.

Similarly, when the first semiconductor material is the gallium nitride-based compound having a formula of AlₓIn_{y}Ga_{1-x-y}N, in which x=0 and y=0, formation of the island-patterned layer is conducted by reacting the gallium source gas with the ammonia gas. Alternatively, when the first semiconductor material is the gallium nitride-based compound having a formula of AlₓIn_{y}Ga_{1-x-y}N, in which 1>x≧0, 1>y≧0, and 1>1−x−y>0, formation of the island-patterned layer is conducted by reacting the gallium source gas with the ammonia gas, the aluminum source gas and the indium source gas.

In addition, the carrier gas used in forming the island-patterned layer may include hydrogen gas (H₂) and nitrogen gas (N₂).

As for epitaxy growth of the base layer of the second semiconductor material, preferably, the second semiconductor material is selected from the group consisting of gallium nitride-based compounds. Preferably, formation of the base layer of the second semiconductor material on the island-patterned layer is conducted by reacting a gallium source gas with an ammonia gas at a reaction temperature ranging from 900° C. to 1500° C. Suitable carrier gases used in the formation of the base layer include hydrogen gas (H₂) and nitrogen gas (N₂). More preferably, during the formation of the base layer, the ratio of the ammonia gas to the carrier gas, such as hydrogen gas (H₂), nitrogen gas (N₂) or a combination thereof, is set at a value ranging from 0.2 to 2.0, and the applied pressure is set at a value ranging from 50 torr to 760 torr, thereby contributing to lateral epitaxy growth of the base layer.

Since the islands of the island-patterned layer are separated from each other, a closed pore defined by two adjacent ones of the separated islands of the island-patterned layer, the semiconductor substrate and the base layer will be formed when the base layer is subsequently formed on the island-patterned layer. The closed pores function as a barrier to prohibit dislocations between the semiconductor substrate and the island-patterned layer from extending upward into the base layer. Hence, the defect density of the base layer can be reduced.

In addition, the base layer starts forming on the island-patterned layer by nucleating at the apex of each of the separated islands of the island-patterned layer, followed by laterally extending to the adjacent islands. The defect density of the base layer can be decreased with an increase in the lateral growth area of the base layer resulting from silicon-doping.

It is noted that by virtue of the closed pores as mentioned above, the semiconductor substrate can be easily separated from the island-patterned layer, if needs, by cutting off a portion of the island-patterned layer. Techniques suitable for forming the island-patterned layer on the semiconductor substrate and for forming the base layer on the island-patterned layer include molecular beam epitaxy (MBE), hydride vapor phase epitaxy (HVPE) and the like, in addition to MOCVD techniques.

In an alternative non-limiting embodiment, a seed layer is formed on the semiconductor substrate, prior to forming the island-patterned layer on the semiconductor substrate. Preferably, the seed layer is made from silicon nitride and is formed by reacting silane with an ammonia gas at a reaction temperature ranging from 500° C. to 1200° C.

In another non-limiting embodiment, a barrier layer is formed on a portion of the seed layer that is not covered by the island-patterned layer, as well as on the island-patterned layer, prior to forming the base layer of the second semiconductor material on the island-patterned layer. Preferably, the barrier layer is made from silicon nitride and is formed by reacting silane with an ammonia gas at a reaction temperature ranging from 500° C. to 1200° C.

During formation of the island-patterned layer of the first semiconductor material, some first semiconductor material residues, which are not formed into the separated islands, may exist on regions of the semiconductor substrate that are not covered by the island-patterned layer. The formation of the barrier layer can prevent the base layer from directly growing on the first semiconductor material residues.

### EXAMPLES

### Example 1

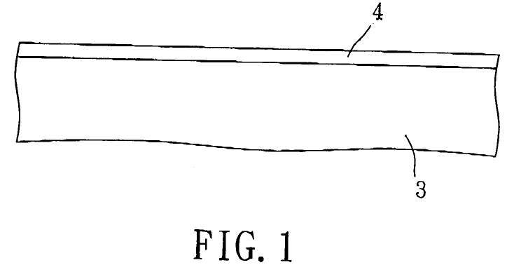

A sapphire substrate 3 having a crystallographic orientation of C plane was placed on a heating plate in a reactor (not shown). The heating plate was subsequently heated to a temperature of 600° C. A mixed flow of about 40 standard cubic centimeter per minute (sccm) of silane (SiH_{4(g)}) and about 40 standard liter per minute (slm) of ammonia (NH_{3(g)}) was introduced into the reactor. A seed layer 4 of silicon nitride, having a thickness larger than 1 Å, was formed on the sapphire substrate 3 through reaction of silane with ammonia (See FIG. 1).

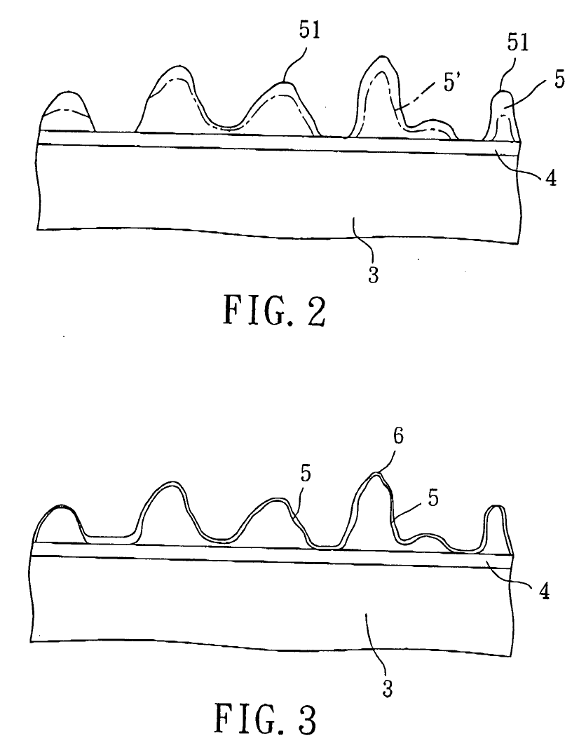

A hydrogen gas was subsequently introduced into the reactor, and the temperature of the wafer susceptor was raised to 1100° C. for annealing the sapphire substrate 3 and the seed layer 4 formed thereon. Next, the temperature of the wafer susceptor was lowered to 800° C., and a mixed flow of 50 sccm of trimethylgallium (TMGa_{(g)}), 20 slm of NH_{3(g)}, and 0.5 sccm of SiH_{4(g)}, was introduced into the reactor, thereby forming an island-patterned layer 5 of GaN that includes a plurality of separated islands 51 on the seed layer 4 (See FIG. 2). It is noted that if no SiH_{4(g)} was introduced into the reactor during formation of the island-patterned layer 5, the height-to-width ratio of each of the separated islands will be reduced, as shown by the imaginary island-patterned layer 5′ in FIG. 2.

After forming the island-patterned layer 5, supply of NH_{3(g)} was maintained, and supply of SiH_{4(g)} was subsequently increased to a flow rate of about 40 sccm. A barrier layer (SiₓN_{y}) 6 was formed on the island-patterned layer S and a portion of the seed layer 4 that is not covered by the island-patterned layer 5, as shown in FIG. 3. The barrier layer 6 thus formed has a thickness larger than 1 Å.

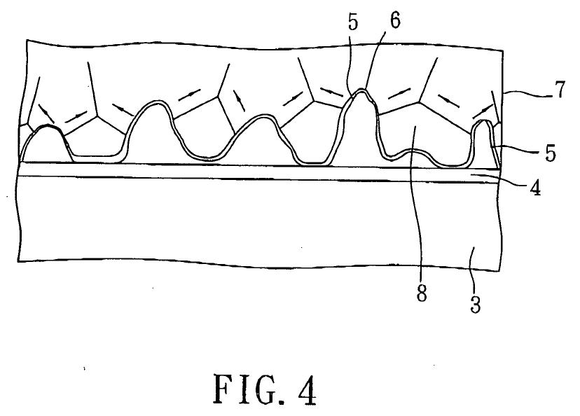

Referring to FIG. 4, the temperature of the wafer susceptor was then raised to about 1100° C., and 120 sccm of TMGa_{(g)} was introduced into the reactor under the presence of NH_{3(g)}. A base layer 7 of GaN was lateral-epitaxially grown on the barrier layer 6 in a direction shown by the arrows, and has a thickness larger than 3 μm. In addition, a plurality of closed pores 8, each of which was defined by two adjacent ones of the separated islands 51 of the island-patterned layer 5, the seed layer 4 and the base layer 7, were formed. As mentioned above, the closed pores 8 function as a barrier to prohibit dislocations between the sapphire substrate 3 and the island-patterned layer 5 from extending upward into the base layer 7 through the seed layer 4. In this example, the defect density of the base layer 7 formed through lateral-epitaxy growth is reduced to 10⁶ to 10⁸ μm⁻². Therefore, the emitted light intensity of the light emitting device including the semiconductor device manufactured by the example of this invention can be greatly enhanced.

### Example 2

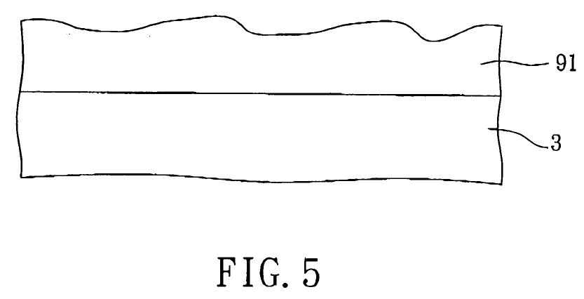

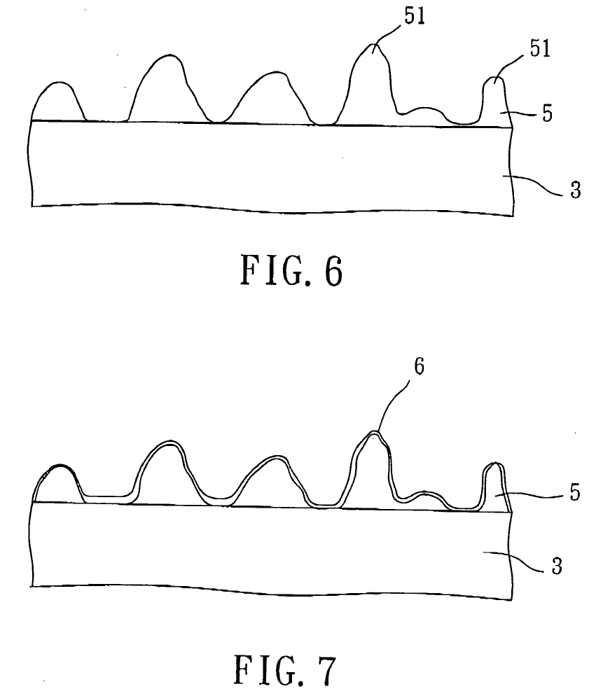

A mixed flow of 15 sccm of TMGa_{(g)} and 20 slm of NH_{3(g)} was introduced into a reactor at a temperature of 600° C. so as to form a continuous layer 91 of GaN covering a sapphire substrate 3 having a crystallographic orientation of C plane (See FIG. 5). Next, the temperature was raised to 950° C., and the partial pressure of NH_{3(g)} was lowered to 6 slm, thereby forming the continuous layer 91 into the island-patterned layer 5 including a plurality of separated islands 51 (See FIG. 6).

After forming the island-patterned layer 5, supply of NH_{3(g)} was maintained, and supply of SiH_{4(g)} was subsequently increased to a flow rate of abut 40 sccm. A barrier layer (SiₓN_{y}) 6 was formed on the island-patterned layer 5 and a portion of the sapphire substrate 3 that is not covered by the island-patterned layer 5, as shown in FIG. 7. The barrier layer 6 has a thickness larger than 1 Å.

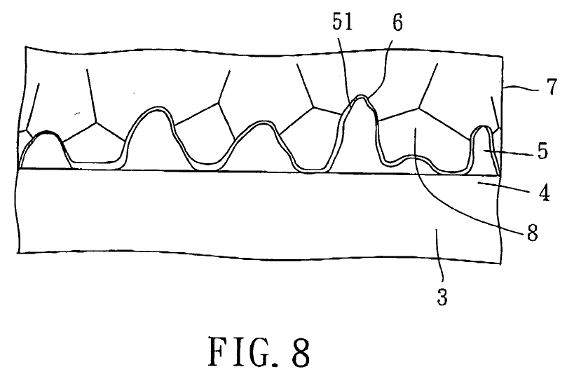

Referring to FIG. 8, the temperature was subsequently raised to about 1000° C., and 120 sccm of TMGa_{(g)} was introduced into the reactor under the presence of NH_{3(g)}. A base layer 7 of GaN was lateral-epitaxially grown on the barrier layer 6 in a direction shown by the arrows, and has a thickness larger than 3 μm. In addition, a plurality of closed pores 8, each of which was defined by two adjacent ones of the separated islands 51 of the island-patterned layer 5, the seed layer 4 and the base layer 7, were formed upon formation of the base layer 7.

It is noted that, compared with Example 1, the seed layer forming step is not necessary and can be omitted in Example 2. Additionally, the configuration of the separated islands 51 depends upon the substrate in use and thus, is not limited to the configuration shown in the accompanying drawings.

According to this invention, by virtue of the island-patterned layer, the base layer is laterally and vertically formed on the semiconductor layer. The intolerably high defect density of the base layer, which is caused by mere vertical growth of the base layer on the semiconductor substrate, can be reduced. Hence, crystallinity of the base layer is greatly improved, and an active layer that is subsequently formed on the base layer will have improved crystallinity and light efficiency.

Incidentally, since the method for manufacturing a semiconductor device according to this invention is relatively simple, production cost of the method of this invention is relatively economic.

While the present invention has been described in connection with what is considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for manufacturing a semiconductor device, comprising:
forming an island-patterned layer of a first semiconductor material on a semiconductor substrate, the island-patterned layer including a plurality of separated islands; and
epitaxially growing a base layer of a second semiconductor material on the island-patterned layer.

2. The method of claim. 1, wherein the first semiconductor material and the second semiconductor material are independently selected from the group consisting of gallium nitride-based compounds.

3. The method of claim 2, wherein the first semiconductor material and the second semiconductor material are independently a gallium nitride-based compound having a formula of AlₓIn_{y}Ga_{1-x-y}N in which 1>x≧0, 1>y≧0, and 1≧1−x−y>0.

4. The method of claim 2, wherein formation of the island-patterned layer on the semiconductor substrate is conducted by reacting a gallium source gas with an ammonia gas at a reaction temperature ranging from 500° C. to 1100° C.

5. The method of claim 4, wherein the reaction temperature ranges from 700° C. to 1100° C.

6. The method of claim 1, further comprising forming a barrier layer on the island-patterned layer prior to forming the base layer of the second semiconductor material on the island-patterned layer.

7. The method of claim 6, wherein the barrier layer is made from silicon nitride and is formed by reacting silane with an ammonia gas at a reaction temperature ranging from 500° C. to 1200° C.

8. The method of claim 2, wherein formation of the island-patterned layer on the semiconductor substrate is conducted by reacting a gallium source gas with silane and an ammonia gas at a reaction temperature ranging from 500° C. to 1100° C.

9. The method of claim 8, wherein the reaction temperature ranges from 700° C. to 1100° C.

10. The method of claim 2, wherein formation of the island-patterned layer on the semiconductor substrate includes:
forming a continuous layer of the first semiconductor material on the semiconductor substrate through reacting a gallium source gas with an ammonia gas at a reaction temperature ranging from 500° C. to 700° C.; and
subsequently raising the reaction temperature to 900° C. to 1100° C. and lowering the partial pressure of the ammonia gas so as to form the continuous layer of the first semiconductor material into the island-patterned layer.

11. The method of claim 2, wherein formation of the base layer of the second semiconductor material on the island-patterned layer is conducted by reacting a gallium source gas with an ammonia gas at a reaction temperature ranging from 900° C. to 1500° C.

12. The method of claim 1, wherein the semiconductor substrate is made from a material selected from the group consisting of silicon carbide, sapphire, lithium aluminate, zinc oxide, aluminum nitride, and silicon.

13. The method of claim 1, further comprising forming a seed layer on the semiconductor substrate, prior to forming the island-patterned layer on the semiconductor substrate.

14. The method of claim 13, wherein the seed layer is made from silicon nitride and is formed by reacting silane with an ammonia gas at a reaction temperature ranging from 500° C. to 1200° C.
